(19) United States
(12) Patent Application Publication
(10) Pub. No.: US 2008/0179692 A1
(43) Pub. Date: Jul. 31, 2008

(54) MASK ROM DEVICES AND METHODS FOR FORMING THE SAME

(76) Inventors: Myung-Jo Chun, Hwaseong-si (KR); Hee-Seog Jeon, Suwon-si (KR); Yong-Kyu Lee, Gwacheon-si (KR); Young-Ho Kim, Hwaseong-si (KR)

Correspondence Address: F. CHAU & ASSOCIATES, LLC, 130 WOODBURY ROAD, WOODBURY, NY, 11797, US

(21) Appl. No.: 12/013,618

(22) Filed: Jan. 14, 2008

(30) Foreign Application Priority Data
Jan. 26, 2007 (KR) 10-2007-08464

(51) Int. Cl. H01L 27/112; H01L 21/8234

(52) U.S. Cl. 257/391; 438/527; 257/E27.102; 257/E21.618

(57) ABSTRACT

A mask read only memory (MROM) device includes first and second gate electrodes formed at on-cell and off-cell regions of a substrate, respectively. A first impurity region is formed at the on-cell region of the substrate so as to be adjacent the first gate electrode. A second impurity region including the same conductivity type as that of the first impurity region is formed at the off-cell region of the substrate so as to be spaced apart from a sidewall of the second gate electrode. A fourth impurity region is formed at the off-cell region to extend from the second impurity region and to overlap with the sidewall of the second gate electrode. The fourth impurity region has a conductivity type opposite to that of the second impurity region and a depth greater than that of the second impurity region.

### CROSS-REFERENCE TO RELATED APPLICATION

This U.S. non-provisional patent application claims priority under 35 U.S.C. §119 of Korean Patent Application No. 10-2007-08464, filed on Jan. 26, 2007, the entire contents of which are hereby incorporated by reference.

### BACKGROUND OF THE INVENTION

The exemplary embodiments disclosed herein relate to read-only memory (ROM) devices and methods of forming the same and, more particularly, to a mask read-only memory (MROM) device and a NOR-type mask read-only memory (NOR-type MROM) device and methods of forming the same.

The read-only memory (ROM) devices are non-volatile memory devices to retain stored data even when power supplies are interrupted. The read-only memory (ROM) devices are classified into a mask read-only memory (MROM), a programmable read-only memory (PROM), an electrically programmable read-only memory (EPROM), and an erasable and electrically programmable read-only memory (EEPROM) according to the method used for storing data.

The mask ROM stores data using a mask including data that the users want during a fabrication process. Once data is stored in the mask ROM, erase and rewrite operations of data are impossible, and only a read operation of the stored data is possible.

A coding is performed to write data into each cell of the mask ROM during the fabrication process used in forming the mask ROM. Conventionally, ion impurities are selectively implanted into predetermined MOS transistor memory cells to code those memory cells into logic “0”.

More specifically, a photoresist pattern is formed on a substrate including MOS transistors to selectively expose the MOS transistors in which a logic “0” has to be stored. Subsequently, impurity ions having a conductivity type opposite to source/drain regions are implanted into channel regions of the exposed MOS transistors.

In this known procedure, the MOS transistor where impurity ions are implanted has a threshold voltage higher than that of the MOS transistor where impurity ions are not implanted. According to a difference between the threshold voltages of the MOS transistors, a switching characteristic of each MOS transistor becomes different. Thus, data stored in each cell may be discriminated. That is, the transistor a channel of which is doped with impurity ions becomes an off-transistor to always output a logic “0”, and the transistor a channel of which is not doped with impurity ions becomes an on-transistor to always output a logic “1”.

Japan laid open publication number 2001-351992 discloses a method of forming the mask ROM using the coding process described above.

In the case that the data is coded using the above-described known method, some problems occur.

First, impurities of a high concentration must be implanted into the channel region so that the off-transistor has a sufficiently high threshold voltage. If an ion implantation process for the impurity doping is performed, however, impurities having a conductivity type opposite to the source/drain regions are highly implanted into portions under the source/drain regions, as well as the channel region. As a result, a junction breakdown voltage between the drain and a bulk substrate becomes low.

Also, an ion implantation process using a high energy must be performed to implant impurities of high concentration into the channel region under a gate electrode of the transistor. When the ion implantation process is performed, however, an ion implantation mask having a sufficiently large thickness must be formed on the region where the on-transistor is formed, so that the impurity ions are not implanted into the region where the on-transistor is formed. A photoresist pattern is usually used as the ion implantation mask. In the case that the photoresist layer is formed to have a large thickness, it is not easy to form a fine pattern of the photoresist layer. Thus, it is difficult to form the mask ROM device to be highly integrated.

Moreover, ion implantation equipment that employs high energy is required to perform the ion implantation process. Thus, the cost for forming the mask ROM device increases.

### SUMMARY OF THE INVENTION

Exemplary embodiments of the present invention provide a mask read-only memory (MROM) device that may include: first and second gate electrodes formed at an on-cell region and an off-cell region of a substrate, respectively; a first impurity region formed at the on-cell region of the substrate so as to be adjacent the first gate electrode; a second impurity region having the same conductivity type as the first impurity formed at the off-cell region so as to be spaced apart from a sidewall of the second gate electrode; and a fourth impurity region extending from the second impurity region to overlap with the sidewall of the second gate electrode, the fourth impurity region having a conductivity type opposite to the second impurity region and a depth greater than the second impurity region.

Exemplary embodiments of the present invention provide a method of forming a mask read-only memory (MROM) device that may include: forming first and second gate electrodes at an on-cell region and an off-cell region of a substrate, respectively; forming a first impurity region at the on-cell region of the substrate so as to be adjacent the first gate electrode; forming a second impurity region having the same conductivity type as the first impurity at the off-cell region of the substrate so as to be spaced apart from a sidewall of the second gate electrode; and forming a fourth impurity region at the off-cell region extending from the second impurity region to overlap with the sidewall of the second gate electrode, the fourth impurity region having a conductivity type opposite to the second impurity and a depth greater than the second impurity region.

Exemplary embodiments of the present invention provide a method of forming a NOR-type mask read-only memory device that may include: forming first and second gate electrodes at an on-cell region and an off-cell region of a cell region of a substrate, respectively; forming third and fourth gate electrodes at a first transistor region and a second transistor region of a logic region of the substrate, respectively; implanting impurities of a second conductivity type under a surface of the substrate located at both sides of the first and second gate electrodes to form a third impurity region adjacent the first gate electrode and a fourth impurity region adjacent the second gate electrode; implanting impurities of a first conductivity type into the on-cell region of the substrate located at both sides of the first gate electrode and into the first transistor region of the substrate located at both sides of the third gate electrode to form first doping regions adjacent the first and third gate electrodes; forming first through fourth spacers on sidewalls of the first through fourth gate electrodes; implanting the impurities of the first conductivity type into a substrate between the first through third spacers to form second doping regions extending from corresponding first doping regions and spaced apart from the corresponding gate electrode at the on-cell region of the cell region and at the first transistor region of the logic circuit region, and to form a second impurity region at the off-cell region, the first and second doping regions at the on-cell region constituting a first impurity region and the first and second doping regions at the first transistor region of the logic region constituting a fifth impurity region; and implanting the impurities of the second conductivity type into the second transistor region of the logic circuit region to form a sixth impurity region.

### BRIEF DESCRIPTION OF THE FIGURES

Exemplary embodiments of the present invention will be understood in more detail from the following descriptions taken in conjunction with the attached figures. In the figures:

FIG. 1 is a cross-sectional view showing cells of a mask read-only memory (MROM) device in accordance with an exemplary embodiment of the present invention.

FIGS. 2 through 5 are cross-sectional views illustrating a method of forming cells of a mask read-only memory (MROM) device as shown in FIG. 1.

FIG. 6 is a cross-sectional view of a mask read-only memory (MROM) device in accordance with an exemplary embodiment of the present invention.

FIGS. 7 through 13 are cross-sectional views illustrating a method of forming a mask read-only memory (MROM) device as shown in FIG. 6.

### DETAILED DESCRIPTION OF EXEMPLARY EMBODIMENTS

Exemplary embodiments of the present invention will now be described more fully with reference to the accompanying drawings. This invention may, however, be embodied in many different forms and should not be construed as being limited to the exemplary embodiments set force herein. Rather, these exemplary embodiments are provided so that this disclosure will be thorough and complete, and will fully convey the scope of the invention to those of ordinary skill in the art.

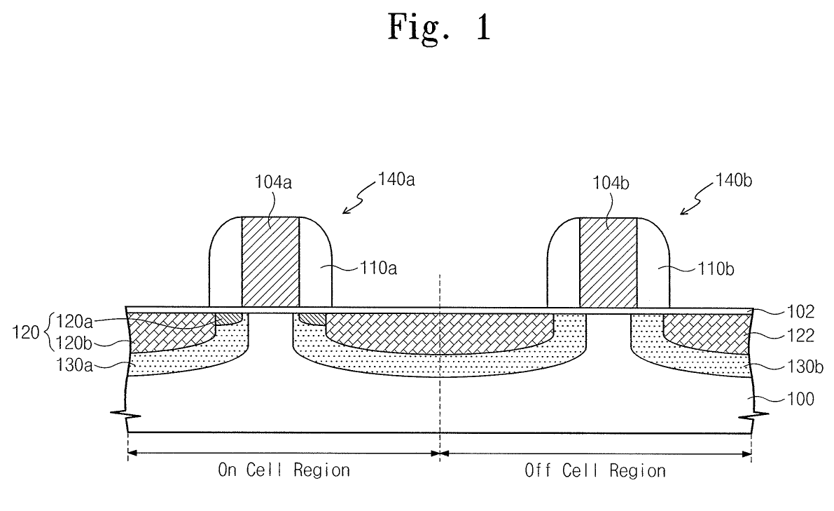

FIG. 1 is a cross-sectional view showing cells of a mask read-only memory (MROM) device in accordance with an exemplary embodiment of the present invention.

Referring to FIG. 1, a substrate 100 is provided to define an on-cell region and an off-cell region. The substrate 100 may include a single crystalline silicon substrate that is lightly doped with p-type impurities.

The mask read-only memory (MROM) device includes an on-cell transistor that is always turned on during a read operation and an off-cell transistor that is always turned off during a read operation. Therefore, the on-cell transistor is formed at the on-cell region of the substrate, and the off-cell transistor is formed at the off-cell region of the substrate. In the present exemplary embodiment, the on-cell transistor is formed of an n-type transistor.

First, the on-cell transistor 140a formed at the on-cell region will be described.

A gate oxide layer 102 is formed on the on-cell region of the substrate 100. The gate oxide layer 102 may be formed of silicon oxide grown by annealing the substrate 100.

A first gate electrode 104a is formed on the gate oxide layer 102 of the on-cell region. The first gate electrode 104a may be formed of conductive material. More specifically, the first gate electrode 104a may be formed of semiconductor material such as doped polysilicon, a conductor such as a metal material, metal silicide, conductive metal nitride, conductive metal oxide, or combinations of these materials.

A first impurity region 120 doped with n-type impurities is formed at the on-cell region of the substrate 100 adjacent a sidewall of the first gate electrode 104a. A portion of the first impurity region 120 may extend to overlap with the sidewall of the first gate electrode 104a. A first spacer 110a may be formed on a sidewall of the first gate electrode 104a.

In this exemplary embodiment, the first impurity region 120 may include a first doping region 120a having a first concentration located at the substrate 100 adjacent the sidewall of the first gate electrode 104a, and a second doping region 120b extending from the first doping region 120a and located at the substrate 100 at a side portion of the first spacer 110a. The second doping region 120b has a second concentration higher than the first concentration and has a depth greater than the first doping region 120a. In this exemplary embodiment, a portion of a third impurity region 130a may be located between the first gate electrode 104a and the first spacer 110a.

The first spacer 110a may be formed of an insulating material, and the first spacer 110a may include silicon nitride. The first spacer 110a may cover the first doping region 120a of the first impurity region 120. That is, the impurity region 120a is located at the substrate 100 under the first spacer 110a to have a concentration relatively lower than the impurity region 120b and the same conductivity type as the impurity region 120b. The first spacer 110a may also cover a portion of the second doping region 120b adjacent the first doping region 120a.

A third impurity region 130a may be formed at the on-cell region. The third impurity region 130a may be formed to have a depth greater than the first impurity region 120. The third impurity region 130 has impurities of a conductivity type opposite to the first impurity region 120. For example, the third impurity region 130a includes p-type impurities. The third impurity region 130a may be formed to overlap with a portion of the first gate electrode 104a. When a voltage higher than a threshold voltage is applied to the first gate electrode 104a of the on-cell transistor 140a, a channel is formed at a substrate under the first gate electrode 104a to maintain an on state.

Hereinafter, an off-cell transistor 140b formed at the off-cell region will be described.

A gate oxide layer 102 is formed on the off-cell region of the substrate 100.

A second gate electrode 104b is formed on the gate oxide layer 102 of the off-cell region. The second gate electrode 104b may be formed of the same conductive material as the first gate electrode 104a. A second spacer 110b may be formed at the sidewall of the second gate electrode 104b. The second spacer may be an insulating spacer. The second spacer 110b may be formed of the same material as the first spacer 110a.

A second impurity region 122 doped with n-type impurities is formed at the off-cell region of the substrate 100 located outside of the second gate electrode 104b. The second impurity region 122 may be spaced apart from a sidewall of the second gate electrode 104b. The second impurity region 122 may have the same impurity concentration and/or the same doping depth as the second doping region 120b of the first impurity region 120.

A fourth impurity region 130b may be formed at the off-cell region to have a depth greater than the second impurity region 122. The fourth impurity region 130b extends to the sidewall of the second gate electrode 140b. The fourth impurity region 130b may extend from the second impurity region 122 to overlap with a portion of the second gate electrode 140b. The fourth impurity region 130b has impurities of a conductivity type opposite to the second impurity region 122. The fourth impurity region 130b has the same conductivity type as the third impurity region 130a of the on-cell region. The fourth impurity region 130b may have substantially the same impurity concentration and/or the same doping depth as the third impurity region 130a of the on-cell region.

In this exemplary embodiment, a portion of the fourth impurity region 130b may be located between the second gate electrode 104b and the second spacer 110b.

In the case of the on-cell transistor 140a, the first doping region 120a having the same conductivity type as the second doping region 120b and a concentration lower than the second doping region 120b extends from the second doping region 120b toward the first gate electrode 104a. In the case of the off-cell transistor 140b, however, the fourth impurity region 130b having a conductivity type opposite to the second impurity region 122 extends from the second impurity region 122 toward the second gate electrode 104b.

In the ease of the off-cell transistor 140b according to the above-described exemplary embodiment, the fourth impurity region 130b prevents the second impurity region 122 from extending to a substrate under the second gate electrode 104b. A threshold voltage of a channel region of the off-cell transistor 140b greatly increases due to an effect of halo ion implantation by the fourth impurity region 130b. Therefore, the threshold voltage of the off-cell transistor 140b increases and characteristics of leakage currents generated from junction regions or the channel region are improved.

Although a voltage is applied to the second gate electrode 104b of the off-cell transistor 140b, the channel region is not formed at a substrate under the second gate electrode 104b. Thus, the off-cell transistor always maintains an off state regardless of the gate voltage.

As shown in FIG. 1, the on-cell region may be adjacent the off-cell region. In this case, a portion of the first impurity region 120 may be connected to a portion of the second impurity region 122. In the same manner, a portion of the third impurity region 130a may be connected to a portion of the fourth impurity region 130b.

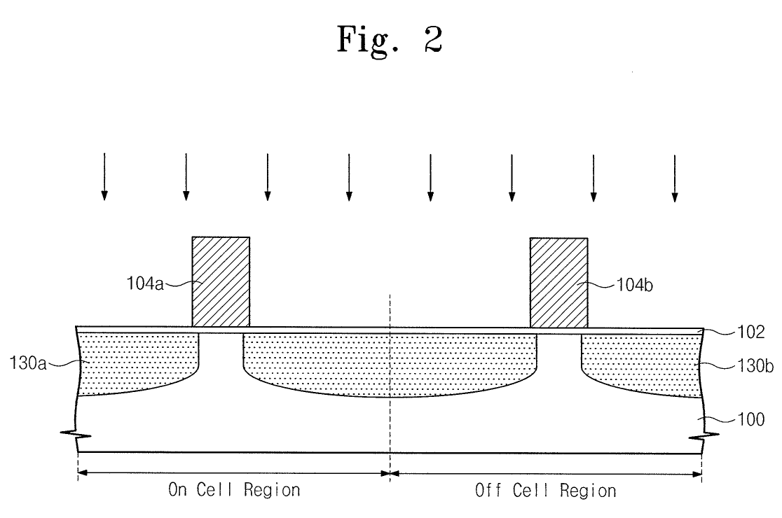

FIGS. 2 through 5 are cross-sectional views illustrating a method of forming cells of a mask read-only memory (MROM) device such as that, shown in FIG. 1.

Referring to FIG. 2, a gate oxide layer 102 is formed on a substrate 100 where an on-cell region and an off-cell region are defined. The substrate 100 may be formed of a single crystalline silicon substrate that is lightly doped with p-type impurities. The gate oxide layer 102 may be formed by thermally oxidizing the substrate 100.

A conductive layer for a gate electrode (not shown) is formed on the gate oxide layer 102. The conductive layer for a gate electrode may be formed of material such as polysilicon, metal, metal silicide, conductive metal nitride, conductive metal oxide, or combinations of these materials. In the present exemplary embodiment, the conductive layer is formed of polysilicon that is easily etched using a dry etching. The conductive layer for a gate electrode is patterned using a photolithography process to form a first gate electrode 104a at the on-cell region and a second gate electrode 104b at the off-cell region.

P-type impurities are implanted into the substrate 100 including the first and second gate electrodes to form third and fourth impurity regions 130a, 130b at the on-cell and off-cell regions, respectively. In this exemplary embodiment, the fourth impurity region 130b may selectively be formed only at the off-cell region, and the third impurity region 130a may not be formed at the on-cell region.

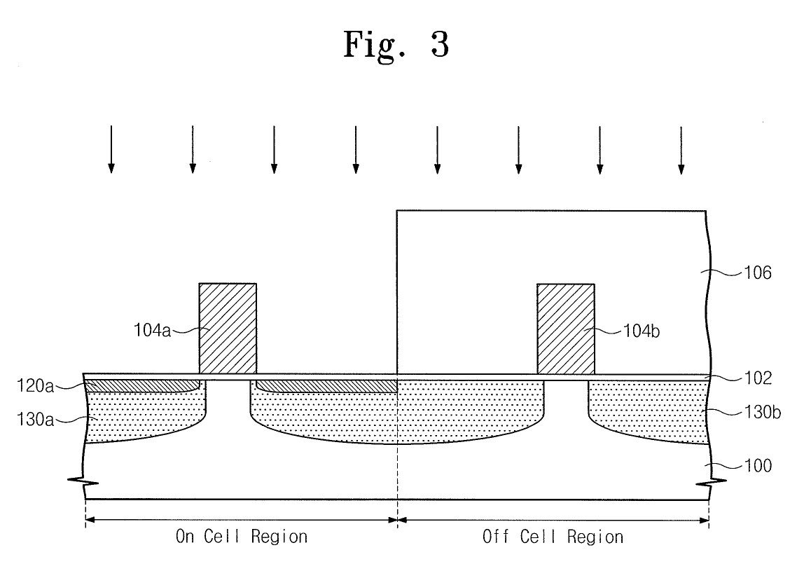

Referring to FIG. 3, an ion implantation mask pattern 106 is formed to cover the off-cell region. The ion implantation mask pattern 106 includes a photoresist pattern formed by a photolithography process. N-type impurities are implanted into the substrate 100 of the on-cell region exposed by the ion implantation mask pattern 106 to form a first doping region 120a having a first concentration. The first doping region 120a may be adjacent a sidewall of the first gate electrode 104a.

Next, the ion implantation mask pattern 106 is removed. In the case that the ion implantation mask pattern 106 is formed of the photoresist pattern, the photoresist pattern may be removed using an ashing process or a strip process.

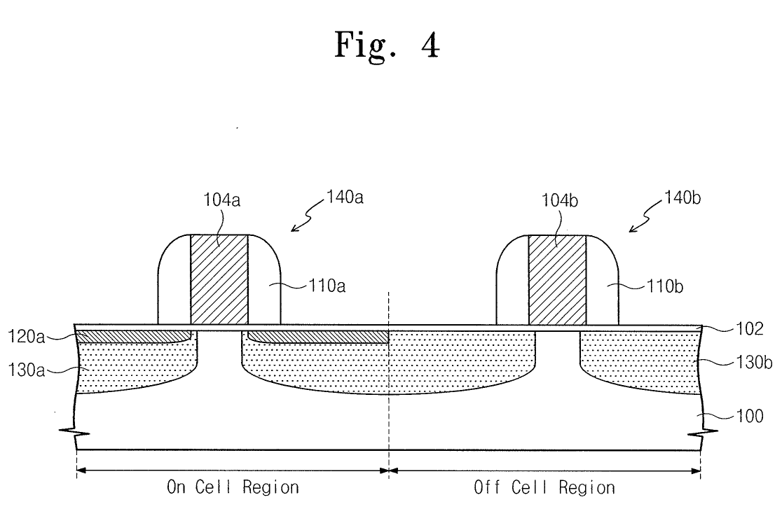

Referring to FIG. 4, an insulating layer (not shown) for a spacer is formed on the sidewalls of the first and second gate electrodes 104a and 104b, and on the gate oxide layer 102. The insulating layer for a spacer may be formed by depositing silicon nitride using a low pressure chemical vapor deposition (LPCVD) process. After that, the insulating layer for a spacer is anisotropically etched to form first and second spacers 110a and 110b on the sidewalls of the first and second gate electrodes 104a, 104b, respectively. At this time, the first and second spacers 110a and 110b are formed to have a thickness that is greater than a distance that impurities doped under the substrate 100 may be diffused toward the first and second gate electrodes 104a, 104b in the subsequent process.

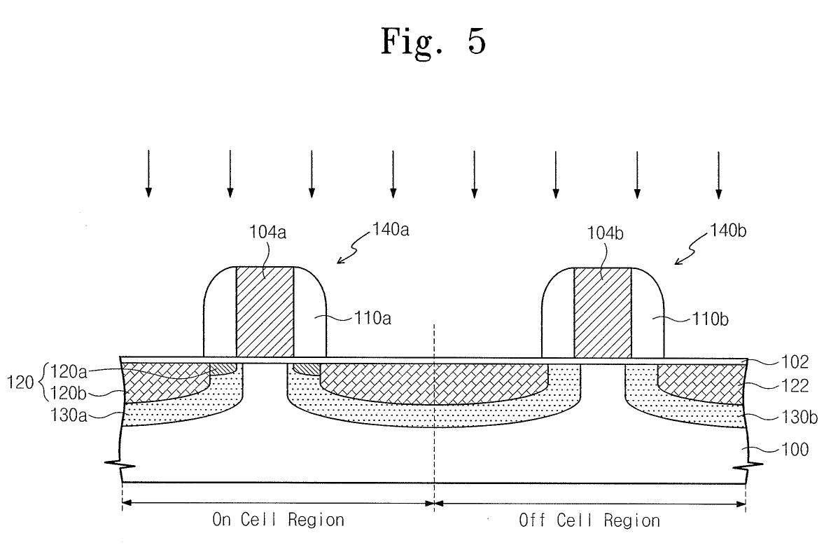

Referring to FIG. 5, n-type impurities are implanted into the surface of the substrate 100 using the gate electrodes and the spacers as an ion implantation mask to form a second doping region 120b at the on-cell region and a second impurity region 122 at the off-cell region.

The second doping region 120b is formed at the on-cell region that is in contact with the first doping region 120a and is located under a substrate of a sidewall of the first spacer 110a. The second doping region 120b has a second concentration higher than the first doping region 120a and a depth greater than the first doping region 120a. A first impurity region 120 may include the first and second doping regions 120a, 120b in the on-cell region. Thus, the first impurity region 120 has a lightly doped drain (LDD) structure.

In the meanwhile, a portion of the second impurity region 122 may be located under a bottom surface of the second spacer 110b. In this exemplary embodiment, the second impurity region 122 may overlap with a portion of the second spacer 110b. Impurities having a concentration higher than the first doping region 120a of the on-cell region are implanted into the second impurity region 122 of the off-cell region. The second impurity region 122 of the off-cell region is formed to have a depth greater than the first doping region 120a of the on-cell region.

The p-type fourth impurity region 130b may prevent the n-type second impurity region 122 from extending to the sidewall of the second gate electrode 104b at the off-cell region. That is, the n-type second impurity region 122 may be prevented from overlapping with the second gate electrode 104b.

The impurities doped in the second impurity region 122 may be diffused during a subsequent process accompanied with a high temperature. Therefore, in order to prevent the second impurity region 122 from overlapping with the second gate electrode 104b even if the impurities doped in the second impurity region 122 are diffused toward the second gate electrode 104b, the second spacer 110b is formed to have a thickness greater than a distance that the impurities doped in the second impurity region 122 may be diffused toward the second gate electrode 104b.

By performing the above-described process, on-cell transistors are formed at the on-cell region and off-cell transistors are formed at the off-cell region.

According to the present exemplary embodiment, forming the off-cell transistors does not require a process of implanting impurities into a channel region, thereby improving an operation characteristic and a reliability of a mask read-only memory (MROM) device.

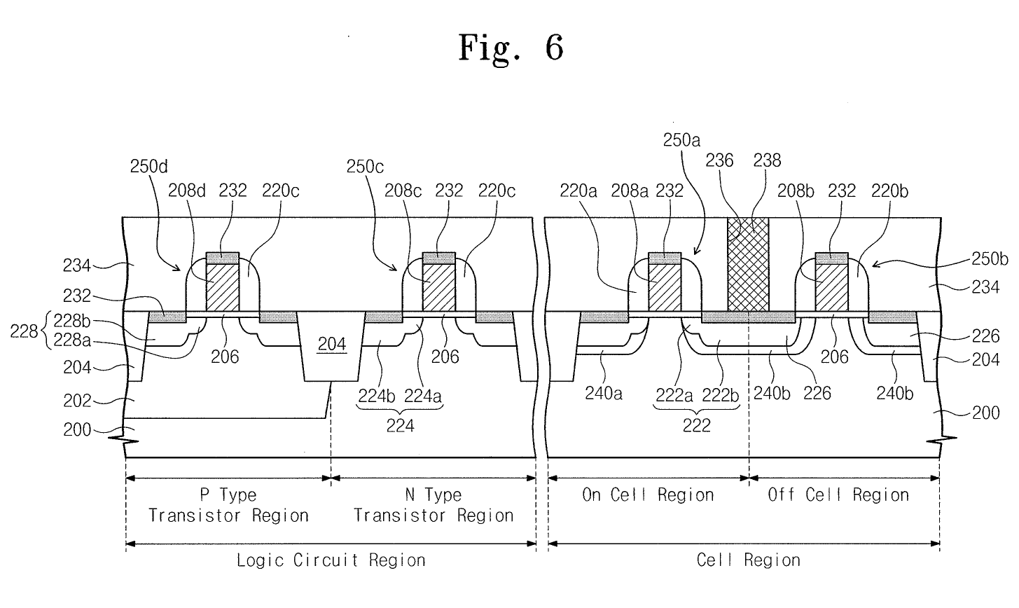

FIG. 6 is a cross-sectional view of a mask read-only memory (MROM) device in accordance with an exemplary embodiment of the present invention.

Referring to FIG. 6, a substrate 200 is provided to define a cell region including an on-cell region and an off-cell region, and a logic circuit region.

An on-cell transistor 250a and an off-cell transistor 250b having data that users want are formed at the cell region. The on-cell transistor 250a and the off-cell transistor 250b have the same structure as the on-cell transistor 140a and the off-cell transistor 140b of the mask read-only memory (MROM) illustrated in FIG. 1.

An n-type transistor 250c and a p-type transistor 250d are formed at the logic circuit region. Hereinafter, at the logic circuit region, the region including the n-type transistor 250c is referred to as an n-type transistor region and the region including the p-type transistor 250d is referred to as a p-type transistor region.

The substrate 200 may include a single crystalline silicon substrate that is lightly doped with p-type impurities. An n-type well region 202 is formed deeply at the p-type transistor region of the logic circuit region.

Device isolation patterns 204 are formed at the substrate 200 to define an active region. More specifically, device isolation patterns 204 are disposed in the cell region to be parallel to a first direction. The device isolation patterns 204 are formed at the logic circuit region to separate n-type transistors and p-type transistors.

A gate oxide layer 206 is formed on a surface of the substrate 200. The gate oxide layer 206 may be formed of silicon oxide grown by annealing the substrate 200.

A number of gate electrode lines 208a and 208b are formed on the gate oxide layer 206 disposed at the on-cell region and the off-cell region. The gate electrode lines 208a and 208b are perpendicular to a number of the device isolation patterns 204. A gate electrode line passing through the on-cell region becomes a gate electrode of the on-cell transistor and a gate electrode line passing through the off-cell region becomes a gate electrode of the off-cell transistor between the gate electrode lines 208a and 208b. Hereinafter, a gate electrode line passing through the on-cell region is referred to as a first gate electrode 208a, and a gate electrode line passing through the off-cell region is referred to as a second gate electrode 208b.

Third and fourth gate electrodes 208c, 208d are formed on the gate oxide layer 206 disposed at the logic circuit region.

The first, second, third, and fourth gate electrodes 208a, 208b, 208c, and 208d, respectively may be formed of semiconductor material, such as doped polysilicon, metal material, metal silicide, conductive metal nitride, conductive metal oxide, or combinations of these materials. In the present exemplary embodiment, the first, second, third, and fourth gate electrodes 208a, 208b, 208c, and 208d, respectively, are formed of doped polysilicon material.

Spacers are formed on sidewalk of the first, second, third, and fourth gate electrodes 208a, 208b, 208c, and 208d, respectively. The spacers may be formed of insulating material. Hereinafter, spacers formed on sidewalls of the first, second, third, and fourth gate electrodes 208a, 208b, 208c, and 208d are referred to as first, second, third, and fourth spacers 220a, 220b, 220c, and 220d, respectively.

A first impurity region 222 having n-type impurities is formed at a portion of the substrate 200 adjacent the sidewall of the first gate electrode 208a. A portion of the first impurity region 222 extends to overlap with the sidewall of the first gate electrode 208a.

The first impurity region 222 includes a first doping region 222a that is adjacent the sidewall of the first gate electrode 208a, and a second doping region 222b that is in contact with the first doping region 222a and is located under a sidewall of the first spacer 220a. The first doping region 222a has a first impurity concentration, and the second doping region 222b has a second impurity concentration higher than the first impurity concentration and a depth greater than the first doping region 222a.

A third impurity region 240a may be formed at the on-cell region to have a depth greater than the first impurity region 222. Impurities of the third impurity region 240a are opposite to those of the first impurity region 222.

If a voltage higher than a threshold voltage is applied to the first gate electrode 208a of the on-cell transistor, a channel is formed under the first gate electrode 208a to maintain a turn-on state.

An n-type second impurity region 226 is formed at the off-cell region to be spaced apart from the second gate electrode 208b. A fourth impurity region 240b may be formed at the off-cell region to have a depth greater than the second impurity region 226. The fourth impurity region 240b extends from the second impurity region 226 toward a side surface of the second gate electrode 208b. The fourth impurity region 240b may extend from the second impurity region 226 to overlap with a portion of the second gate electrode 208b. The fourth impurity region 240b has impurities of a conductivity type opposite to those of the second impurity region 226. The fourth impurity region 240b may be the same conductivity type as the third impurity region 240a. The fourth impurity region 240b may have substantially the same concentration and depth as the third impurity region 240a.

Even though a voltage is applied to the second gate electrode 208b of the off-cell transistor, a channel is not formed under the second gate electrode 208b. Thus, the off-cell transistor always maintains an off state, regardless of the voltage applied, to the second gate electrode 208b.

A threshold voltage of the channel of the off-cell transistor greatly increases due to an effect of a halo ion implantation by the fourth impurity region 240b. Therefore, characteristics of leakage currents generated from junctions and/or the channel region are improved.

A fifth impurity region 224 having n-type impurities is formed at the substrate 200 adjacent a sidewall of the third gate electrode 208c of the logic circuit region. A portion of the fifth impurity region 224 extends to overlap with the sidewall of the third, gate electrode 208c. The fifth impurity region 224 may have a lightly doped drain (LDD) structure. That is, an impurity concentration of the region 224a adjacent the sidewall of the third gate electrode 208c is relatively lower than that of the other region 224b of the fifth impurity region 224.

A sixth impurity region 228 having p-type impurities is formed at the substrate 200 adjacent a sidewall of the fourth gate electrode 208d at the logic circuit region. A portion of the sixth impurity region 228 extends to overlap with the sidewall of the third gate electrode 208d. The sixth impurity region 228 may have the same lightly doped drain (LDD) structure as the first and fifth impurity regions 222, 224. The sixth impurity region 228, however, may have a conductivity type opposite to that of the first and fifth impurity regions 222, and 224, respectively.

A metal silicide layer pattern 232 is formed on the substrate 200 disposed between the spacers and the device isolation pattern. That is, the metal silicide layer pattern 232 is formed on the impurity regions 222, 224, 226, 240a, 240b, and 228 and the first, second, third, and fourth gate electrodes 208a, 208b, 208c, and 208d, respectively. The metal silicide layer patterns 232 reduce a resistance of each of the first, second, third, and fourth gate electrodes 208a, 208b, 208c, and 208d, respectively, and the impurity regions 222, 224, 226 and 228.

Examples of materials that may be used as the metal silicide layer pattern 232 are tungsten silicide, cobalt silicide, titanium silicide or the like. The material may be used alone or combinations of the materials may be used.

An interlayer insulating layer 234 is formed at the substrate 200 to cover the first, second, third, and fourth gate electrodes 208a, 208b, 208c, and 208d, respectively. A contact hole 236 is formed at the interlayer insulating layer 234 to expose at least one of the impurity regions 222, 226, 224 and 228. A contact 238 is formed in the contact hole 236 to be in contact with the impurity regions 222, 226, 224 and 228.

Interconnection lines (not shown) are formed on the interlayer insulating layer 234 and are connected to the contact 238. The wiring lines include a bit line and a common source line.

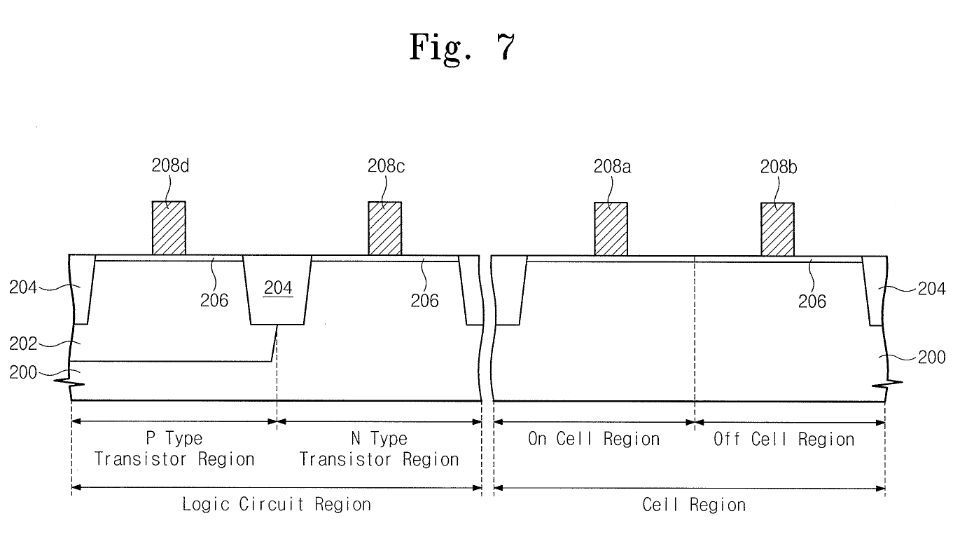

FIGS. 7 through 13 are cross-sectional views illustrating an exemplary embodiment of a method of forming a mask read-only memory (MROM) device such as shown in FIG. 6.

Referring to FIG. 7, a substrate 200 is provided to define a cell region and a logic circuit region. The cell region includes an on-cell region and an off-cell region. The logic circuit region includes an n-type transistor region and a p-type transistor region. The substrate 200 may be a single crystalline silicon substrate that is lightly doped with p-type impurities.

N-type impurities are selectively implanted into a portion of the logic circuit region, for example, the p-type transistor region, to form an n-type well region 202. For example, a first photoresist pattern (not shown) is formed on the substrate 200 to expose the p-type transistor region of the logic circuit region.

N-type impurities of a low concentration are implanted into the exposed substrate using the first photoresist pattern as an ion implantation mask.

A device isolation layer pattern 204 is formed at the substrate 200 to define an active region. More specifically, trenches (not shown) are formed at the substrate 200 by etching a portion of the substrate 200. In this exemplary embodiment, isolated type trenches are disposed in the cell region to be parallel to a first direction, and in the logic circuit region, trenches are disposed at regions where the p-type transistor and the n-type transistor are separated. After that, insulating material fills the trenches to complete the device isolation layer pattern 204.

The trenches isolated in the cell region are all parallel with each other. Thus, the device isolation layer patterns 204 are all parallel with each other.

A gate oxide layer 206 is formed on the active region of the substrate 200. The gate oxide layer 206 may be formed by thermally oxidizing the substrate 200.

A conductive layer (not shown) for a gate electrode is formed on the gate oxide layer 206. Materials that may be used as the conductive layer are polysilicon, metal, metal silicide, conductive metal nitride, conductive metal oxide, or combinations of these materials. In the present exemplary embodiment, the conductive layer is formed of polysilicon that is easily etched through a dry etching.

After that, the conductive layer is patterned using a photolithography process to form gate electrode lines at the on-cell region and, simultaneously, gate electrodes of an isolated type at the logic circuit region, as shown in FIG. 7.

A gate electrode line located at the on-cell region is referred to as a first gate electrode 208a and a gate electrode line located at the off-cell region is referred to as a second gate electrode 208b.

Also, a conductive layer pattern used as a gate electrode of the n-type transistor is referred to as a third gate electrode 208c and a conductive layer pattern used as a gate electrode of the p-type transistor is referred to as a fourth gate electrode 208d at the logic circuit region.

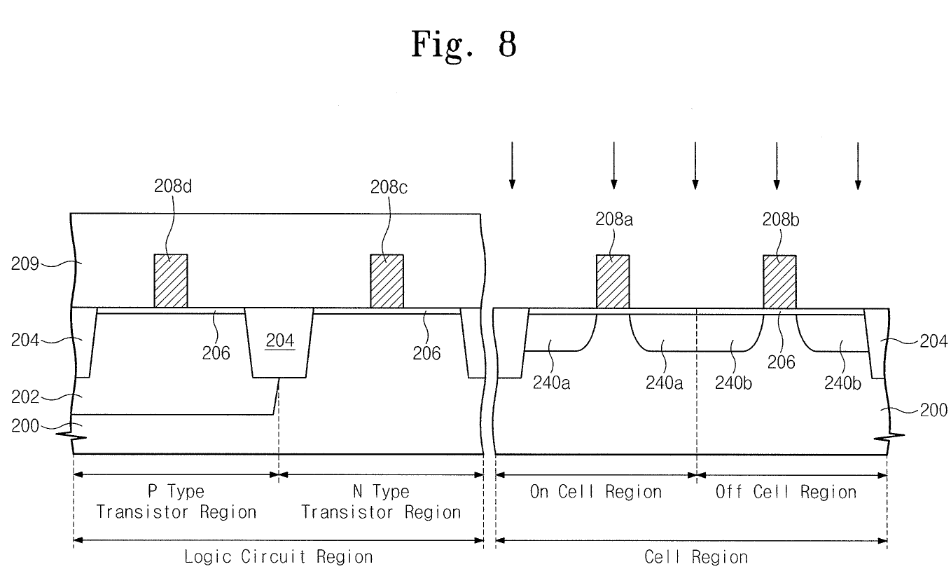

Referring to FIG. 8, a second photoresist pattern 209 is formed on the substrate 200 to selectively expose the cell transistor region of the cell region.

After that, p-type impurities are implanted into the substrate located at both sides of the first and second gate electrodes 208a and 208b to form third and fourth impurity regions 240a and 240b. The third impurity region 240a is formed at the on-cell region and the fourth impurity region 240b is formed at the off-cell region. In this exemplary embodiment, the third impurity region 240a may not be formed at the on-cell region. For example, in the case that the second photoresist pattern 209 covers the on-cell region, the fourth impurity region 240b may selectively be formed at the off-cell region. A high-voltage p-type well and/or an ultra-high-voltage p-type source/drain may be formed using the second photoresist pattern 209 as an ion implantation mask. That is, forming the third and fourth impurity regions 240a and 240b does not require a further mask. The mask for forming the high-voltage p-type well and/or the ultra-high-voltage p-type source/drain may be changed so as to be used to form the third and fourth impurity regions 240a and 240b.

The second photoresist pattern 209 may be removed through ashing and strip processes.

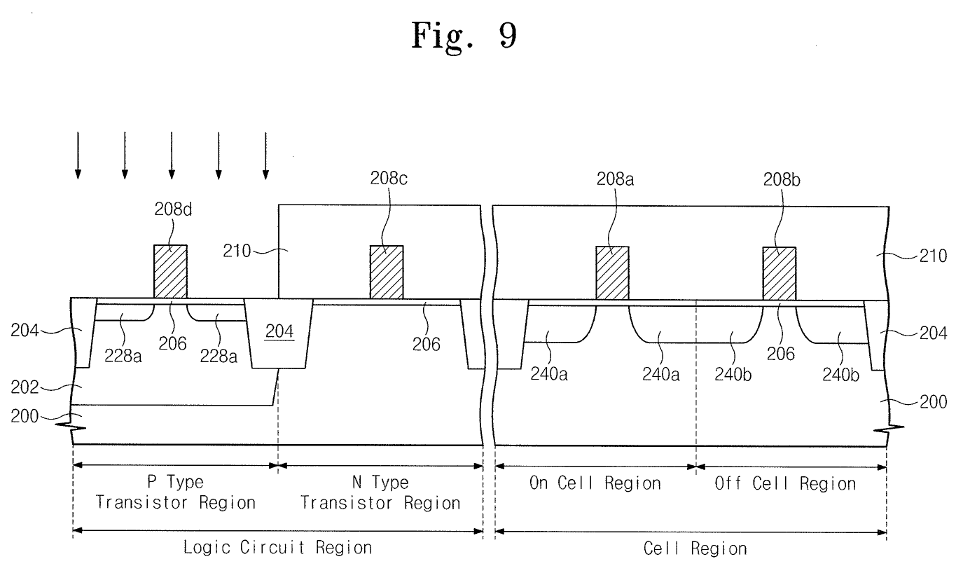

Referring to FIG. 9, a third photoresist pattern 210 is formed at the logic circuit region to selectively expose the p-type transistor region. After that, p-type impurities are implanted into the substrate 200 located at both sides of the fourth gate electrode 208d using the third photoresist pattern 210 as an etching mask. As a result, a third doping region 228a of a sixth impurity region is formed. The third doping region 228a may overlap with a sidewall of the fourth gate electrode 208d.

The third photoresist pattern 210 may be removed through an ashing process and a strip process.

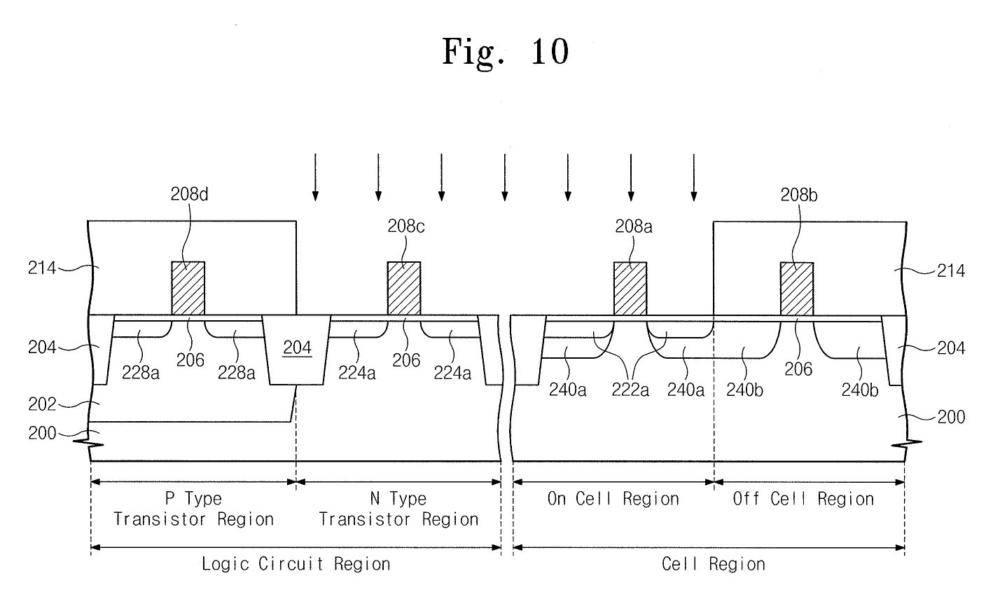

Referring to FIG. 10, a fourth photoresist pattern 214 is formed on the substrate 200 to selectively expose the n-type transistor region of the logic circuit region and the on-cell region of the cell region. That is, the fourth photoresist pattern 214 covers the p-type transistor region of the logic circuit region and the off-cell region of the cell region.

After that, n-type impurities are implanted into the substrate 200 located at both sides of the first and third gate electrodes 208a and 208c using the fourth photoresist pattern 214 as a mask. As a result, a first doping region 222a of the first impurity region is formed at a substrate located at both sides of the first gate electrode 208a, and a first doping region 224a of a fifth impurity region is formed at a substrate located at both sides of the third gate electrode 208c. The first doping region 222a of the first impurity region may be formed to overlap with the sidewall of first gate electrode 208a. Similarly, the first doping region 224a of a fifth impurity region may be formed to overlap with the sidewall of the third gate electrode 208c.

As explained above, a fourth photoresist pattern 214 is formed to mask the p-type transistor at the logic circuit region and the off-cell reunion at the cell region. That is, data that users want are coded into the cell region by masking the off-cell region. Thus, additional photolithography process for data coding and implanting impurities into channels are not required.

The fourth photoresist pattern 214 may be removed using an ashing process and a strip process.

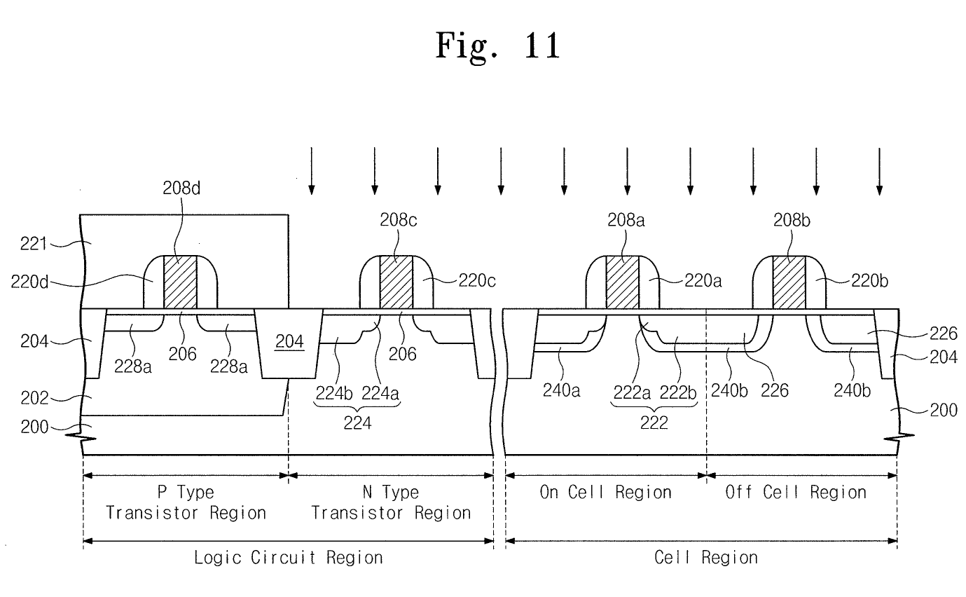

Referring to FIG. 11, an insulating layer (not shown) is formed at the sidewalk of the gate electrode lines, and the third and fourth gate electrodes 208c and 208d. The insulating layer for the spacer may be formed of silicon nitride.

The insulating layer for the spacer is anisotropically etched to form spacers at the sidewalls of the gate electrode lines and the third and fourth gate electrodes 208c and 208d. Hereinafter, spacers that are formed at sidewalls of the first and second gate electrodes 208a and 208b are referred to as a first spacer 220a and a second spacer 220b, respectively. Spacers that are formed at sidewalls of the third and fourth gate electrodes 208c and 208d are referred to as a third spacer 220c and a fourth spacer 220d, respectively.

Next, a fifth photoresist pattern 221 is formed at the logic circuit region to cover the p-type transistor region.

High concentration n-type impurities are implanted into the on-cell and off-cell regions, and the n-type transistor region of the logic circuit region using the fifth photoresist pattern 221 as an ion implantation mask.

By performing the ion implantation process, a second doping region 222b of the first impurity region is formed at the on-cell region and a second impurity region 226 is formed at the off-cell region. A second doping region 224b of a fifth impurity region is formed at the n-type transistor region of the logic circuit region. The second doping region 222b of the first impurity region may be formed to have a concentration lower than that of the first doping region 222a and a depth greater than the first doping region 222a. The second doping region 222b of the first impurity region may be formed so as to be spaced apart from the sidewall of the first gate electrode 208a. The second doping region 224b of the fifth impurity region may be formed so as to have the same depth and concentration as the second doping region 222b of the first impurity region.

The first impurity region 222 includes the first and second doping regions 222a, 222b. The first impurity region 222 has a lightly doped drain (LDD) structure. Similarly, The fifth impurity region 224 includes the first and second doping region 224a, 224b, and the fifth impurity region 224 has a lightly doped drain (LDD) structure.

A portion of the second impurity region 226 may be located under the second spacer 220b. That is, the second, impurity region 226 has to be located so as not to overlap with the second gate electrode 208b.

Impurities doped at the second impurity region 226 may be diffused during a subsequent process accompanied with a high temperature. Thus, even if the impurities are diffused toward the second gate electrode 208b, in order that the second impurities do not overlap the second gate electrode 208b the second spacer 220b is formed to have a thickness that is greater than a distance that the impurities may be diffused toward the second gate electrode 208b.

After the ion implantation process, an on-cell transistor is formed at the on-cell region and an off-cell transistor is formed at the off-cell region. Also, an n-type transistor is formed at a portion of the logic circuit region.

The second impurity region 226 of the off-cell transistor does not have a doping region corresponding to the first doping region of the first impurity region 222 of the on-cell region. That is, at the on-cell transistor region, the first doping region 222a is connected to the second doping region 222b adjacent the gate electrode. At the off-cell transistor region, however, a fourth impurity region 240b is connected to the second impurity region adjacent the gate electrode and extends toward the sidewall of the gate electrode. A threshold voltage of the off-cell transistor region increases due to the fourth impurity region 240b.

After the ion implantation process, the fifth photoresist pattern 221 used as an ion implantation mask is removed through an ashing process and a strip process.

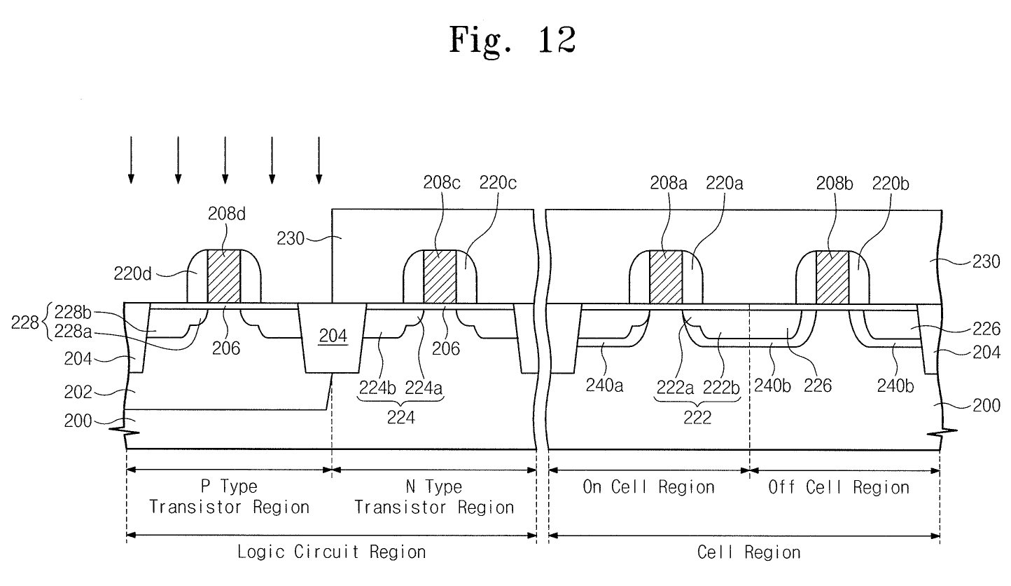

Referring to FIG. 12, a sixth photoresist pattern 230 is formed to selectively expose the p-type transistor region of the logic circuit region. The sixth photoresist pattern 230 covers the on-cell and off-cell regions, and the n-type transistor region at the logic circuit region.

Next high concentration p-type impurities are implanted into the p-type transistor region of the logic circuit region using the sixth photoresist pattern 230 as an ion implantation mask to form a fourth doping region 228b of a sixth impurity region spaced apart from the sidewall of the fourth gate electrode 208d. The fourth doping region 228b is formed to have a concentration higher than that of a third doping region 228a and to have a depth greater than that of a third doping region 228a. The sixth impurity region 228 includes the third and fourth doping regions 228a, 228b. Thus, the sixth impurity region 228 has a lightly doped drain (LDD) structure.

By performing the above process, the p-type transistor is formed at a portion of the logic circuit region.

After the ion implantation process, the sixth photoresist pattern 230 used as an ion implantation mask is removed through an ashing process and a strip process.

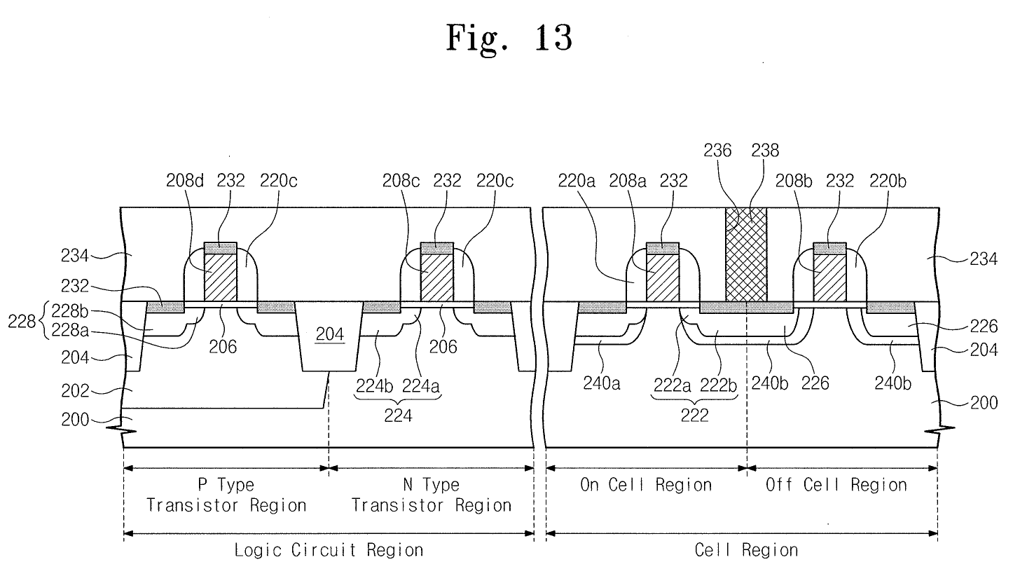

Referring to FIG. 13, the gate oxide layers 206 that remain at the surface of the substrate 200 exposed at the side surface of the spacers 220a, 220b, 220c and 220d are removed by a cleaning process. After the cleaning process, the gate oxide layers 206 remain only under the gate electrodes 208a, 208b, 208c and 208d and the spacers 220a, 220b, 220c and 220d.

After this, a metal layer (not shown) is deposited on the surface of the exposed substrate 200, spacers 220a, 220b, 220c, and 220d, and on the first, second, third, and fourth gate electrodes 208a, 208b, 208c and 208d. Materials that may be used as the metal layer are tungsten, cobalt, or titanium, and the material may be used alone or combinations of these materials.

A capping layer (not shown) is further formed on the metal layer. Material that may be used as the capping layer is titanium or titanium nitride. The material may be used alone or combinations of these materials may be used. The capping layer reduces an interface oxide layer formed on surfaces of the substrate 100 and the first, second, third, and fourth gate electrodes 208a, 208b, 208c, and 208d, and leads to a stable silicidatian reaction during a subsequent annealing process.

Next, the metal layer reacts to the surfaces of the first, second, third, and fourth gate electrodes 208a, 208b, 208c, and 208d by annealing the substrate 200 to form a metal silicide layer pattern 232. At this time, the metal layer formed on the spacer remains without any reaction during the annealing process.

When the metal silicide layer pattern 232 is formed, the surfaces of the substrate 200 and the first, second, third, and fourth gate electrodes 208a, 208b, 208c, and 208d, respectively, react on each other so as to be consumed slightly. The metal silicide layer pattern 232 may be thinly formed, so that the impurity regions 2.22, 226, 224, and 228 are not excessively consumed.

The annealing process for the metal silicide layer pattern 232 may be performed by a rapid thermal process (RTP) or a furnace annealing process. The annealing process may be performed using a single step annealing process or a multi step annealing process. The temperature of the steps of the multi step annealing process may be different from each other.

After this, the unreacted metal layer and capping layer that remain on the first, second, third, and fourth spacers 220a, 220b, 220c, and 220d are removed. The unreacted metal layer and capping layer may be removed using a wet etching process.

An interlayer insulating layer 234 is formed on the substrate 200 to cover the first, second, third, and fourth gate electrodes 208a, 208b, 208c, and 208d. The interlayer insulating layer 234 may be formed of silicon oxide.

Next, a portion of the Interlayer insulating layer 234 is etched away to form a contact hole 236 that exposes at least one surface of the first, second, third, and fourth impurity regions 222, 226, 224, and 228, respectively.

The contact hole 236 is filled with a conductive material and the conductive material is patterned to form a contact 238 that is in contact with the impurity regions.

Interconnection lines (not shown) are formed so as to be connected to the contact 238. The interconnection lines include bit lines and common source lines.

According to the present exemplary embodiment, data coding of a NOR-type mask read-only memory (MROM) device does not require a process of implanting impurities into a channel region, thereby improving an operation characteristic and a reliability of a mask read-only memory (MROM). Also, because a separate process for data coding is not required, the process becomes simplified. As a result, a cost for forming a memory device is reduced.

What is claimed is:

1. A mask read-only memory (MROM) cell, comprising:
first and second gate electrodes formed at an on-cell region and an off-cell region of a substrate, respectively;
a first impurity region formed at the on-cell region of the substrate so as to be adjacent the first gate electrode;
a second impurity region having a same conductivity type as the first impurity region formed at the off-cell region of the substrate so as to be spaced apart from a sidewall of the second gate electrode; and
a fourth impurity region formed at the off-cell region of the substrate, wherein the fourth impurity region extends from the second impurity region to overlap with the sidewall of the second gate electrode, and the fourth impurity region having a conductivity type opposite to a conductivity type of the second impurity region and having a depth greater than a depth of the second impurity region.

2. The mask read-only memory (MROM) cell of claim 1, further comprising:
a third impurity region formed at the on-cell region of the substrate so as to overlap with a sidewall of the first gate electrode, the third impurity region having a conductivity type opposite to a conductivity type of the first impurity region and a depth greater than a depth of the first impurity region.

3. The mask read-only memory (MROM) cell of claim 1, wherein the first impurity region comprises:
a first doping region that overlaps with a sidewall of the first gate electrode; and
a second doping region connected to the first doping region and spaced apart from the sidewall of the first gate electrode, the second doping region including an impurity concentration higher than an impurity concentration of the first doping region.

4. The mask read-only memory (MROM) cell of claim 1, wherein the first and second gate electrodes comprise polysilicon doped with an impurity.

5. The mask read-only memory (MROM) cell of claim 1, wherein the first and second impurity regions are connected to each other.

6. The mask read-only memory (MROM) cell of claim 2, further comprising:
a third gate electrode formed at a logic circuit region of the substrate; and
a fifth impurity region formed at the logic circuit region of the substrate so as to be adjacent the third gate electrode.

7. The mask read-only memory (MROM) cell of claim 6, wherein the fifth impurity region has a same conductivity type as the first impurity region.

8. The mask read-only memory (MROM) cell of claim 6, further comprising:
a fourth gate electrode formed at the logic circuit region of the substrate; and
a sixth impurity region formed at the logic circuit region of the substrate so as to be adjacent the fourth gate electrode, the sixth impurity region having a conductivity type opposite to a conductivity type of the fifth impurity region.

9. A method of forming a mask read-only memory (MROM) cell, comprising:
forming first and second gate electrodes at an on-cell region and an off-cell region of a substrate, respectively;
forming a first impurity region at the on-cell region of the substrate so as to be adjacent the first gate electrode;
forming a second impurity region having a same conductivity type as a conductivity type of the first impurity region at the off-cell region of the substrate so as to be spaced apart from a sidewall of the second gate electrode; and
forming a fourth impurity region at the off-cell region extending from the second impurity region to overlap with the sidewall of the second gate electrode, the fourth impurity region having a conductivity type opposite to a conductivity type of the second impurity region and a depth greater than a depth of the second impurity region.

10. The method of forming a mask read-only memory (MROM) cell of claim 9, further comprising, when forming the forth impurity region:
forming a third impurity region at the on-cell region of the substrate so as to overlap with a sidewall of the first gate electrode, the third impurity region having a conductivity type opposite to a conductivity type of the first impurity region and a depth greater than a depth of the first impurity region.

11. The method of forming a mask read-only memory (MROM) cell of claim 9, wherein forming the first impurity region comprises:
forming an ion implantation mask to cover the off-cell region after forming the fourth impurity region;
implanting a first concentration impurity into the on-cell region exposed by the ion implantation mask to form a first doping region overlapping with the sidewall of the first gate electrode; and
implanting impurities into the on-cell region to form a second doping region having a second concentration higher than the first concentration after formation of spacers on sidewalls of the first and second gate electrodes, the second doping region extending from the first doping region to be spaced apart from the sidewall of the first gate electrode.

12. The method of forming a mask read-only memory (MROM) cell of claim 10, wherein the second impurity region is formed by implanting the second concentration impurity.

13. The method of forming a mask read-only memory (MROM) cell of claim 10, wherein the first and second impurity regions are formed within the fourth impurity region.

14. A method of forming a NOR type mask read only memory (MROM) device, comprising:
forming first and second gate electrodes at an on-cell region and an off-cell region of a cell region of a substrate, respectively, and third and fourth gate electrodes at first and second transistor regions of a logic circuit region of the substrate;
implanting impurities of a second conductivity type under a surface of the substrate located at both sides of the first and second gate electrodes to form a third impurity region adjacent the first gate electrode and a fourth impurity region adjacent the second gate electrode;
implanting impurities of a first conductivity type into the on-cell region located at both sides of the first gate electrode and into the first transistor region located at both sides of the third gate electrode to form first doping regions adjacent the first and third gate electrodes;
forming first, second, third, and fourth spacers on sidewalls of the first, second, third, and fourth gate electrodes, respectively;
implanting impurities of the first conductivity type into a substrate between the first, second, and third spacers to form second doping regions extending from corresponding first doping regions and spaced apart from the corresponding gate electrode at the on-cell region of the cell region and at the first transistor region of the logic circuit region, and to form a second impurity region at the off-cell region, the first and second doping regions at the on-cell region constituting a first impurity region and the first and second doping regions at the first transistor region constituting a fifth impurity region; and
implanting impurities of the second conductivity type into the second transistor region of the logic circuit region to form a sixth impurity region.

15. The method of forming a NOR type mask read only memory (MROM) device of claim 14, further comprising:
forming an interlayer insulating layer at the substrate to cover the first, second, third, and fourth gate electrodes;
etching a portion of the interlayer insulating layer to form a contact hole exposing at least one region of the first, second, third, fourth, fifth, and sixth impurity regions; and
filling an inside of the contact hole with a conductive material to form a contact.

16. The method of forming a NOR type mask read only memory (MROM) device of claim 14, wherein the first, second, third, and fourth gate electrodes include polysilicon doped with an impurity.

17. The method of forming a NOR type mask read only memory (MROM) device of claim 14, further comprising:
forming a metal silicide pattern on the first, second, third, and fourth gate electrodes and a substrate located at a side portion of the first, second, third, and fourth spacers, respectively.

18. The method of forming a NOR type mask read only memory (MROM) device of claim 14, wherein forming the first doping regions comprises:
forming an ion implantation mask pattern to cover the off-cell region and the second transistor region; and
implanting the first conductivity type impurities into the on-cell region and the first transistor region exposed by the ion implantation mask pattern.

19. The method of forming a NOR type mask read only memory (MROM) device of claim 14, further comprising:
implanting the first conductivity type impurities into the logic circuit region to form a channel region before forming the fourth gate electrode.

20. The method of forming a NOR type mask read only memory (MROM) device of claim 14, wherein forming the third and fourth impurity region comprises:
forming an ion implantation mask pattern to cover the logic circuit region;
implanting the second conductivity type impurities into the on-cell and off-cell regions.
